(19) United States
(12) Patent Application Publication
(10) Pub. No.: US 2024/0268218 A1
(43) Pub. Date: Aug. 8, 2024

(54) METAL OXIDE NANOPARTICLES AND METHOD FOR MANUFACTURING THE SAME AND A LIGHT EMITTING DEVICE INCLUDING METAL OXIDE NANOPARTICLES

(71) Applicant: Samsung Display Co., Ltd., Yongin-si (KR)

(72) Inventors: SOOHO LEE, Yongin-si (KR); Jungho JO, Yongin-si (KR); YUNHYUK KO, Yongin-si (KR); Yun Ku JUNG, Yongin-si (KR)

(21) Appl. No.: 18/516,015

(22) Filed: Nov. 21, 2023

(30) Foreign Application Priority Data
Feb. 1, 2023 (KR) 10-2023-0013839

(51) Int. Cl. H10K 85/30; C07F 3/06

(52) U.S. Cl. CPC H10K 85/381; C07F 3/06; H10K 50/16

(57) ABSTRACT

A metal oxide nanoparticle includes a compound represented by Chemical Formula 1 and an alkyl amine ligand having 8 to 18 carbon atoms positioned on a surface of the compound.

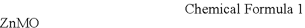

In Chemical Formula 1, M may be one selected from among Ca, Zr, Al, Li, Mg, Ni, Y, W, Co, and Ga.

### CROSS-REFERENCE TO RELATED APPLICATION

This application claims priority to and the benefit of Korean Patent Application No. 10-2023-0013839, filed in the Korean Intellectual Property Office on Feb. 1, 2023, the entire content of which is incorporated herein by reference.

### BACKGROUND

### 1. Field

Embodiments of the present disclosure relate to metal oxide nanoparticles, a method for preparing the same, and a light emitting device including the metal oxide nanoparticles.

### 2. Description of the Related Art

A light emitting device includes an anode, a cathode, and an emission layer formed therebetween, excitons are generated by combination of holes injected from the anode and electrons injected from the cathode in the emission layer, and light is generated as the excitons fall from an excited state to a ground state.

The light emitting device may be driven with a low voltage and may be configured to be relatively lightweight and thin, and has excellent or suitable characteristics such as a viewing angle, contrast, and a response speed, and thus an application range is expanding from personal portable devices to televisions.

The above information disclosed in this Background section is only for enhancement of understanding of the background of the present disclosure, and therefore, it may contain information that does not form the prior art that is already suitable in this country to a person of ordinary skill in the art.

### SUMMARY

Aspects of embodiments are directed toward a metal oxide nanoparticle, a method for preparing the same, and a light emitting device having improved light emitting properties by including metal oxide nanoparticles.

Additional aspects will be set forth in part in the description which follows and, in part, will be apparent from the description, or may be learned by practice of the presented embodiments of the disclosure.

An embodiment of the present disclosure provides a metal oxide nanoparticle including: a compound represented by Chemical Formula 1 and an alkyl amine ligand having 8 to 18 carbon atoms positioned on a surface of the compound.

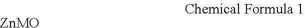

In Chemical Formula 1, M may be one selected from among Ca, Zr, Al, Li, Mg, Ni, Y, W, Co, and Ga.

A size of the metal oxide nanoparticle may be 3 nm to 20 nm.

The metal oxide nanoparticle (e.g., metal oxide nanoparticles) may be formed of one selected from among ZnMgO, ZnLiO, ZnAlO, and ZnGaO.

An embodiment of the present disclosure provides a preparing method of a ZnMgO nanoparticle, including: synthesizing ZnMgO utilizing a Sol-Gel method at a temperature of 10° C. or less; and adding an amine to the synthesized ZnMgO.

The prepared ZnMgO nanoparticle may include an alkyl amine ligand having 8 to 18 carbon atoms positioned on a surface of the prepared ZnMgO nanoparticle (e.g., ZnMgO nanoparticles).

It may further include performing surface treatment by adding Mg to the synthesized ZnMgO.

A size (e.g., average size or diameter) of the prepared ZnMgO nanoparticle (e.g., ZnMgO nanoparticles) may be 3 nm to 20 nm.

A size deviation of the prepared ZnMgO nanoparticle may be within 15% based on a median value.

A size of the ZnMgO nanoparticle may increase through the adding of the amine to the synthesized ZnMgO.

An embodiment of the present disclosure may include a preparing method of a ZnMgO nanoparticle, including: synthesizing ZnO utilizing a Sol-Gel method at a temperature of 10° C. or less; obtaining ZnMgO by adding Mg to the synthesized ZnO; and adding an amine to the obtained ZnMgO.

The prepared ZnMgO nanoparticle may include an alkyl amine ligand having 8 to 18 carbon atoms positioned on a surface of the prepared ZnMgO nanoparticles.

A size of the prepared ZnMgO nanoparticle may be 3 nm to 20 nm.

A size deviation of the prepared ZnMgO nanoparticle may be within 15% based on a median value.

An embodiment of the present disclosure provides a light emitting device including: a first electrode; an electron transport layer disposed on the first electrode; an emission layer disposed on the electron transport layer; a hole transport layer disposed on the emission layer; and a second electrode disposed on the hole transport layer, wherein the electron transport layer includes metal oxide nanoparticles, the metal oxide nanoparticles include a compound represented by Chemical Formula 1 and an alkyl amine ligand having 8 to 18 carbon atoms positioned on a surface of the compound.

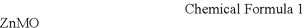

In Chemical Formula 1, M may be one selected from among of Ca, Zr, Al, Li, Mg, Ni, Y, W, Co, and Ga.

A size of the metal oxide nanoparticles may be 3 nm to 20 nm.

The metal oxide nanoparticles may be formed of one selected from among ZnMgO, ZnLiO, ZnAlO, and ZnGaO.

A size deviation of the metal oxide nanoparticle included in the electron transport layer may be within 15% of a median size value of the prepared nanoparticle.

The first electrode may be a reflecting electrode, and the second electrode may be a transflective electrode.

The first electrode may be a transflective electrode, and the second electrode may be a reflective electrode.

### BRIEF DESCRIPTION OF THE DRAWINGS

FIG. 1 illustrates a process flow chart showing a preparing process of metal oxide nanoparticles according to an embodiment.

FIG. 2 illustrates an image of ZnMgO nanoparticles without amine treatment.

FIG. 3 illustrates an image of ZnMgO nanoparticles subjected to amine treatment.

FIG. 4 illustrates absorption spectra according to wavelengths for the ZnMgO nanoparticles of FIG. 2 (Example 1) and the ZnMgO nanoparticles of FIG. 3 (Example 2).

FIG. 5 illustrates a preparing process of ZnMgO nanoparticles according to an embodiment.

FIG. 6 illustrates ZnO nanoparticles without amine treatment.

FIG. 7 illustrates ZnMgO nanoparticles subjected to Mg surface treatment and amine treatment.

FIG. 8 illustrates absorption spectra according to wavelengths for the ZnO nanoparticles of FIG. 6 (Example 3) and the ZnMgO nanoparticles of FIG. 7 (Example 4).

FIG. 9 illustrates absorption spectra before and after amine treatment for ZnMgO nanoparticles prepared through a Sol-Gel method at room temperature (25° C.).

FIG. 10 schematically illustrates a light emitting device according to an embodiment.

FIG. 11 illustrates a J-V graph for Example 8 including amine-treated metal oxide nanoparticles and Example 7 including non-amine-treated metal oxide nanoparticles.

FIG. 12 illustrates light efficiency for Example 8 including amine-treated metal oxide nanoparticles and Example 7 including non-amine-treated metal oxide nanoparticles.

### DETAILED DESCRIPTION

The present disclosure will be described more fully hereinafter with reference to the accompanying drawings, in which embodiments of the present disclosure are shown. As those skilled in the art would realize, the described embodiments may be modified in one or more suitable ways, all without departing from the spirit or scope of the present disclosure.

To clearly describe the present disclosure, parts that are irrelevant to the description are omitted, and like numerals refer to like or similar constituent elements throughout the specification.

Further, because sizes and thicknesses of constituent members shown in the accompanying drawings are arbitrarily given for better understanding and ease of description, the present disclosure is not limited to the illustrated sizes and thicknesses. In the drawings, the thicknesses of layers, films, panels, regions, etc., are exaggerated for clarity. In the drawings, for better understanding and ease of description, the thicknesses of some layers and areas are exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” refers to positioned on or below the object portion, and does not necessarily refer to positioned on the upper side of the object portion based on a gravitational direction.

In some embodiments, unless explicitly described to the contrary, the word “comprise” and variations such as “comprises” or “comprising” will be understood to imply the inclusion of stated elements but not the exclusion of any other elements.

Further, throughout the specification, the phrase “in a plan view” refers to when an object portion is viewed from above, and the phrase “in a cross-sectional view” refers to refers to when a cross-section taken by vertically cutting an object portion is viewed from the side.

Hereinafter, metal oxide nanoparticles, a method for preparing the same, and a display device including the metal oxide nanoparticles according to an embodiment will be described in more detail with reference to the accompanying drawings.

The metal oxide nanoparticles according to an embodiment may be a compound represented by Formula 1.

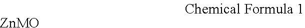

In Chemical Formula 1, M may be one selected from among Ca, Zr, Al, Li, Mg, Ni, Y, W, Co, and Ga.

A compound of Chemical Formula 1 may be in the form of ZnO doped with the metal represented by M, and when expressed more specifically by reflecting doping concentration, it may be a compound represented by Chemical Formula 2.

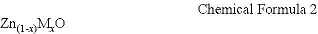

In Chemical Formula 1, M may be one selected from among Ca, Zr, Al, Li, Mg, Ni, Y, W, Co, and Ga. In this case, x may be in a range of 0.01 to 0.5. For example, the doping concentration of M for ZnO may be up to 50%.

In some embodiments, the metal oxide nanoparticles according to the present embodiment may include an alkyl amine ligand positioned on a surface thereof. In this case, the number of carbon atoms of the alkyl amine may be 8 to 18.

In some embodiments, a size of the metal oxide nanoparticles according to the present embodiment may be at least 3 nm and at most 20 nm. More specifically, it may be at least 5 nm and at most 20 nm. Although described separately later, the metal oxide nanoparticles according to the present embodiment are characterized in that the size of the metal oxide nanoparticles is improved and the content (e.g., amount) of the doping material M is increased through amine treatment. For example, when M is Mg, ZnMgO that is not treated with amine has a particle size of about 3 nm, but when treated with amine, the particle size may increase to about 5 nm or more.

The metal oxide nanoparticles according to the present embodiment are formed by amine treatment, and an alkyl amine ligand is positioned on the surface. In this case, a number of carbon atoms of the alkyl amine may be 8 to 18. When the number of carbon atoms of the alkyl amine is 8 or less, dispersibility in a non-polar solvent may be poor, which is undesirable, and when the number of carbon atoms of the alkyl amine is 18 or more, an effect of the ligand may be increased in order to decrease the conductivity. For example, when the metal oxide nanoparticles according to the present embodiment are applied as an electron transport layer of the light emitting device, when the number of carbon atoms of the alkyl amine is 18 or more, electrical conductivity is reduced and thus more voltage must be applied.

Table 1 shows results of measuring dispersibility and conductivity according to the number of carbon atoms of the alkylamine ligand positioned on the surface of the metal oxide nanoparticles according to the present embodiment. Referring to Table 1, it can be seen that, when the number of carbon atoms is 8 or less, the dispersibility in octane is reduced, and when the number of carbon atoms is 18 or more, the electrical conductivity decreases, so the voltage to flow a same current (5 mA/cm²) is increased.

TABLE 1

| | Dispersibility | V @ 5 mA/cm² |
|---|---|---|
| | in Octane | (Electron only device) |
| Carbon number 4 | X | X |
| (butylamine) | | |
| Carbon number 18 | ◯ | 0.85 |
| (oleylamine) | | |
| Carbon number >18 | ◯ | 2.0 |
| (eicosylamine) | | |

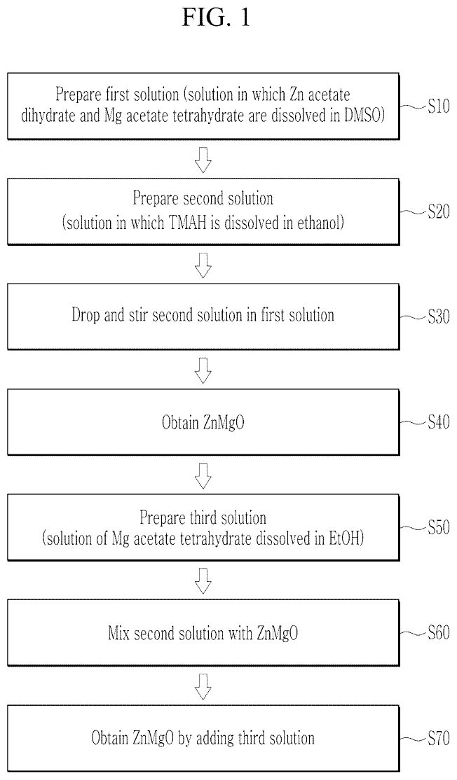

Then, a preparing method of metal oxide nanoparticles according to an embodiment of the present disclosure will be described. FIG. 1 illustrates a process flow chart showing a preparing process of metal oxide nanoparticles according to an embodiment. FIG. 1 illustrates a case where metal oxide nanoparticles are ZnMgO. Referring to FIG. 1, first, a first solution is prepared (S10). In this case, the first solution may be a solution in which Zn acetate dihydrate and Mg acetate tetrahydrate are dissolved in DMSO. For example, the first solution may be a solution containing a Zn precursor and a Mg precursor. According to another embodiment, a type or kind and solvent of the precursor may vary.

In some embodiments, a second solution is prepared (S20). In this case, the second solution may be a solution in which TMAH is dissolved in ethanol.

Next, the second solution is dropped and stirred in the first solution (S30). Thereafter, ZnMgO thus formed is obtained (S40).

In some embodiments, such a ZnMgO formation process (S10, S20, S30, and S40) may be performed at 10° C. or less. When ZnMgO is formed at room temperature (25° C.), a change in particle size does not occur even after amine treatment. However, as described above, when ZnMgO is formed at a temperature of 10° C. or lower, the particle size is increased by subsequent amine treatment.

In some embodiments, a third solution is prepared (S50). The third solution may be a solution of Mg acetate tetrahydrate dissolved in EtOH. The third solution is utilized for surface treatment of ZnMgO.

This third solution is mixed with the previously prepared ZnMgO (S60).

Next, amine is added to obtain ZnMgO (S70). In this case, the amine may be a first amine, a second amine, or a third amine.

For example, in the method for preparing metal oxide nanoparticles according to the present embodiment, after forming ZnMgO utilizing the Sol-Gel method at a temperature of 10° C. or less, an alkyl amine may be positioned on the surface through amine treatment. Through this preparing process, it is possible to improve a size of the metal oxide nanoparticles, improve uniformity, and increase a doping concentration.

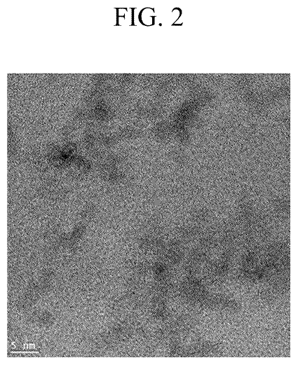

FIG. 2 illustrates an image of ZnMgO nanoparticles without amine treatment. For example, the ZnMgO nanoparticles according to the embodiment of FIG. 2 are particles prepared through the preparing process from steps S10 to S40 of FIG. 1.

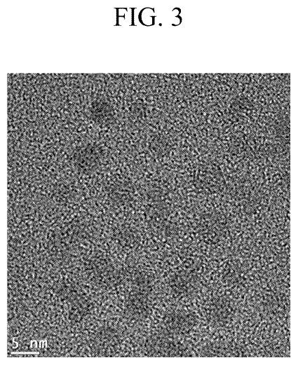

FIG. 3 illustrates an image of ZnMgO nanoparticles subjected to amine treatment. For example, the ZnMgO nanoparticles according to the embodiment of FIG. 3 are particles prepared through the preparing process from steps S10 to S70 of FIG. 1.

Comparing the sizes of the ZnMgO nanoparticles of FIG. 2 and FIG. 3, it can be seen that the size of the ZnMgO nanoparticles of FIG. 3 is larger than that of FIG. 2. In some embodiments, a content (e.g., amount) of Mg included in the nanoparticles of FIG. 3 is higher than that of Mg included in the nanoparticles of FIG. 2.

Table 2 shows Mg contents and particle sizes of the ZnMgO nanoparticles of FIG. 2 and the ZnMgO nanoparticles of FIG. 3.

TABLE 2

| | Example 1 | Example 2 |
|---|---|---|
| | ZnMgO of FIG. 2 | ZnMgO of FIG. 3 |
| | (Before amine | (After amine |
| | treatment) | treatment) |
| Mg content | 15.2% | 20.5% |
| (e.g., amount) | | |
| Particle size | 3.2 ± 1.0 nm | 5.5 ± 0.8 nm |

As can be seen in Table 2, after the amine treatment, the size of the ZnMgO nanoparticles is increased and the Mg content (e.g., amount) is also increased. As the size of the metal oxide nanoparticles increases and the content (e.g., amount) of the dopant (Mg) increases, light emitting efficiency of the light emitting device including the metal oxide nanoparticles may be improved.

In some embodiments, as can be seen in Table 2, size distribution of the ZnMgO nanoparticles prepared according to this example is 5.5±0.8 nm, which was located within 15% of a median size value of 5.5 nm. For example, it can be seen that ZnMgO nanoparticles having a substantially uniform particle size are formed by the preparing method according to the present embodiment.

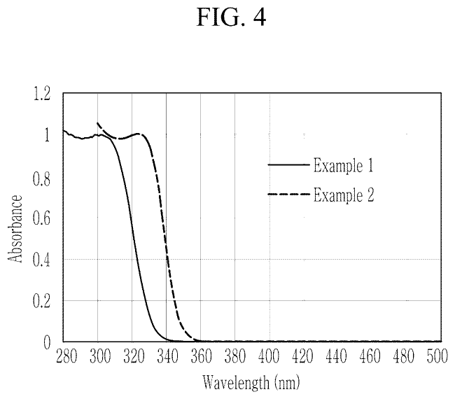

FIG. 4 illustrates absorption spectra according to wavelengths for the ZnMgO nanoparticles of FIG. 2 (Example 1) and the ZnMgO nanoparticles of FIG. 3 (Example 2). As can be seen in FIG. 4, it can be seen that absorption spectrum shifts to the right due to a change in particle size. For example, because the size of the ZnMgO nanoparticles of FIG. 3 is larger than that of the ZnMgO nanoparticles of FIG. 2, it can be seen that a peak of the absorption spectrum was also red-shifted.

In FIG. 1 to FIG. 4, examples of amine treatment after forming ZnMgO nanoparticles have been described, and according to another embodiment, ZnMgO nanoparticles may be formed through Mg surface treatment and amine treatment after forming ZnO nanoparticles. Hereinafter, this embodiment will be described in more detail.

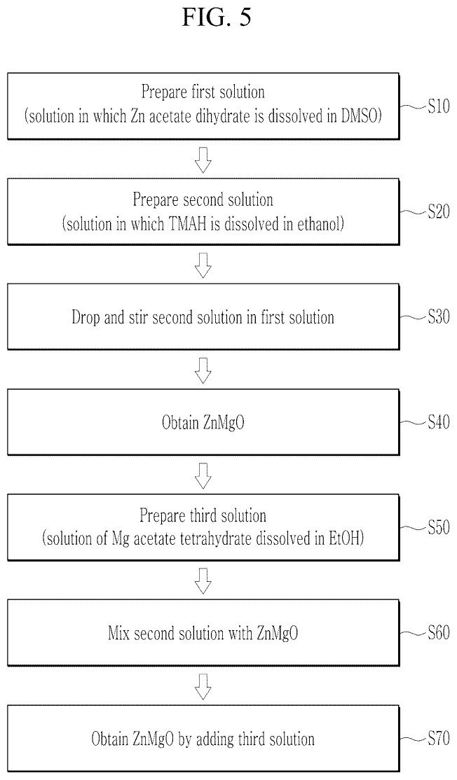

FIG. 5 illustrates a preparing process of ZnMgO nanoparticles according to an embodiment. Referring to FIG. 5, a first solution is prepared (S10). In this case, the first solution may be a solution in which Zn acetate dihydrate is dissolved in DMSO. For example, the first solution may be a solution containing a Zn precursor. According to another embodiment, a type or kind and solvent of the precursor may vary.

In some embodiments, a second solution is prepared (S20). In this case, the second solution may be a solution in which TMAH is dissolved in ethanol.

Next, the second solution is dropped and stirred in the first solution (S30).

Thereafter, ZnO thus formed is obtained (S40).

In this case, such a ZnO formation process (S10, S20, S30, and S40) may be performed at 10° C. or less. As described above, when ZnO is formed at room temperature of 25° C., a change in particle size does not occur even after amine treatment. However, as described above, when ZnO is formed at a temperature of 10° C. or lower, the particle size is increased by the amine treatment described later.

In some embodiments, a third solution is prepared (S50). The third solution may be a solution of Mg acetate tetrahydrate dissolved in EtOH.

This third solution is mixed with the previously prepared ZnO (S60). The third solution is utilized for surface treatment of ZnO.

Next, amine is added to obtain ZnMgO (S70). In this case, the amine may be a first amine, a second amine, or a third amine.

For example, in the method for preparing metal oxide nanoparticles according to the present embodiment, after forming ZnO utilizing the Sol-Gel method at a temperature of 10° C. or less, ZnMgO is obtained through Mg surface treatment, and then amine treatment is performed on the surface form alkyl amines. Through this preparing process, it is possible to improve a size of the metal oxide nanoparticles, improve uniformity, and increase a doping concentration.

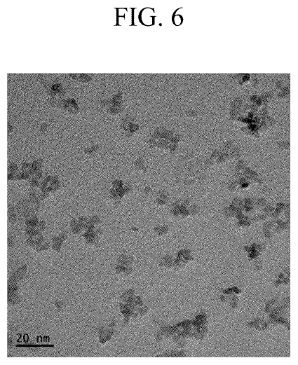

FIG. 6 illustrates ZnO nanoparticles without amine treatment. For example, the ZnO nanoparticles according to the embodiment of FIG. 6 are particles prepared through the preparing process from steps S10 to S40 of FIG. 5.

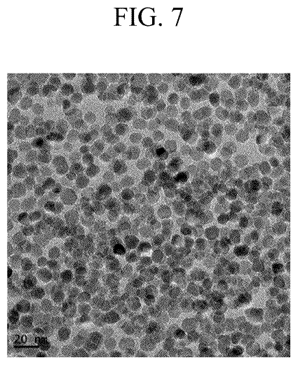

FIG. 7 illustrates ZnMgO nanoparticles subjected to Mg surface treatment and amine treatment. For example, the ZnMgO nanoparticles according to the embodiment of FIG. 7 are particles prepared through the preparing process from steps S10 to S70 of FIG. 7.

Comparing the sizes of the nanoparticles of FIG. 6 and FIG. 7, it can be seen that the size of the nanoparticles of FIG. 7 is larger than the size of the nanoparticles of FIG. 6.

In some embodiments, the nanoparticles of FIG. 6 do not contain Mg, but the nanoparticles of FIG. 7 contain Mg by Mg treatment.

Table 3 shows the Mg content (e.g., amount) and particle size for the nanoparticles of FIG. 6 and FIG. 7.

TABLE 3

| | Example 3 | Example 4 |
|---|---|---|
| | ZnO of FIG. 6 | ZnMgO of FIG. 7 |
| | (Before amine | (After amine |
| | treatment) | treatment) |
| Mg content | 0% | 10.3% |
| (e.g., amount) | | |
| (e.g., amount) | | |
| Particle size | 4.3 ± 1.4 nm | 10.5 ± 1.2 nm |

As can be seen in Table 3, after the amine treatment, the size of the ZnMgO nanoparticles is increased and the Mg content (e.g., amount) is increased. Although this will be separately described later, as the size of the metal oxide nanoparticles increases and the content (e.g., amount) of the dopant (Mg) increases, light emitting efficiency of the light emitting device including the metal oxide nanoparticles may be improved.

In some embodiments, as can be seen in Table 3, size distribution of the ZnMgO nanoparticles prepared according to this example is 10.5±1.2 nm, which was located within 15% of a median size value of 10.5 nm. For example, it can be seen that ZnMgO nanoparticles having a substantially uniform particle size are formed by the preparing method according to the present embodiment.

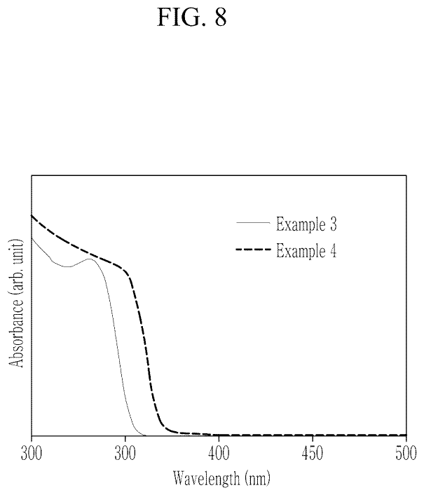

FIG. 8 illustrates absorption spectra according to wavelengths for the ZnO nanoparticles of FIG. 6 (Example 3) and the ZnMgO nanoparticles of FIG. 7 (Example 4). As can be seen in FIG. 8, it can be seen that absorption spectrum shifts to the right due to a change in particle size. For example, because the size of the ZnO nanoparticles of FIG. 7 is larger than that of the ZnMgO nanoparticles of FIG. 6, it can be seen that a peak of the absorption spectrum was also red-shifted.

As described above, formation of ZnO or ZnMgO nanoparticles before amine treatment is performed at a temperature of 10° C. or less. When the ZnO or ZnMgO nanoparticles are formed at a temperature of 10° C. or higher, the size of the nanoparticles may not increase even when the amine treatment is performed.

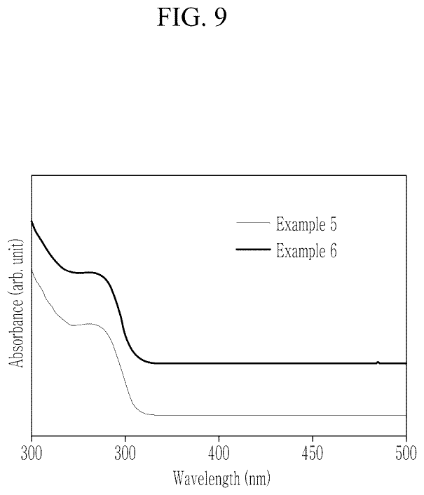

FIG. 9 illustrates absorption spectra before and after amine treatment for ZnMgO nanoparticles prepared through a Sol-Gel method at room temperature (25° C.). In Example 5 of FIG. 9, ZnMgO nanoparticles prepared at room temperature are not treated with amine, and in Example 6 of FIG. 9, amine treatment is performed on ZnMgO nanoparticles prepared at room temperature. Referring to FIG. 9, when the ZnMgO nanoparticles are formed at room temperature, it can be seen that there is no peak shift in the absorption spectrum before and after amine treatment. In FIG. 9, no peak shift of the absorption spectrum is observed for Example 5 and Example 6. This indicates that in the case of ZnMgO prepared at room temperature, the size of the ZnMgO nanoparticles did not increase even after amine treatment.

For example, in the case of FIG. 4 and FIG. 8 in which nanoparticles are prepared at 10° C. or less, red shift of absorption spectrum peaks is confirmed before and after amine treatment. However, in the case of FIG. 9 where nanoparticles are prepared at room temperature (e.g., 25° C.), red shift of absorption spectrum peaks before and after amine treatment do not appear. Accordingly, it can be seen that synthesizing ZnO or ZnMgO nanoparticles at a temperature of 10° C. or less is an important factor.

Metal oxide nanoparticles having a large size and an increased dopant content (e.g., amount), prepared in the above manner, may be utilized as an electron transport layer of a light emitting device. When these metal oxide nanoparticles are utilized as an electron transport layer, emission characteristics of the light emitting device may be improved.

Then, an effect of the present disclosure according to one or more suitable doping materials and amine treatment materials will be described.

Table 4 shows a content (e.g., amount) of the doping material before and after amine treatment and a change in particle size before and after amine treatment, while varying the amine treatment material and the doping material. In some embodiments, relative device efficiency before and after amine treatment is measured and presented. In the previous embodiment, the case where the doping material was Mg was mainly described, but in the following, experiments are conducted for the case where the doping materials are Mg, Li, Al, and Ga, respectively, and results thereof are described.

TABLE 4

| | | | Doping | | |
|---|---|---|---|---|---|
| | | | material | | |
| | | | content | | |
| | | | (e.g., | | Relative |
| | | | amount) | Particle | device |
| | | | (e.g., | size | effi- |
| | | | amount) | change | ciency |
| | | | before/ | before/ | before/ |
| | | | after | after | after |
| | Amine | | amine | amine | amine |
| | treated | Doping | treat- | treat- | treat- |
| | material | material | ment | ment | ment |
| Experi- | ZnO | Mg | 0%/10.3% | 4.3 ± 1.4/ | 1.12 |
| mental | | | | 10.5 ± 1.2 nm | |
| Example | | | | | |
| 1-1 | | | | | |
| Experi- | ZnMgO | | 15.2/20.5% | 3.2 ± 1.0/ | 1.44 |
| mental | | | | 5.5 ± 0.8 nm | |
| Example | | | | | |
| 1-2 | | | | | |
| Experi- | ZnO | Li | 0%/3.1% | 4.3 ± 1.4/ | 1.08 |
| mental | | | | 10.2 ± 1.1 nm | |
| Example | | | | | |
| 2-1 | | | | | |
| Experi- | ZnLiO | | 1.0%/4.8% | 2.9 ± 1.2/ | 1.39 |
| mental | | | | 4.8 ± 0.7 nm | |
| Example | | | | | |
| 2-2 | | | | | |
| Experi- | ZnO | Al | 0%/4.9% | 4.3 ± 1.4/ | 1.02 |
| mental | | | | 11.3 ± 1.3 nm | |
| Example | | | | | |
| 3-1 | | | | | |
| Experi- | ZnAlO | | 4.2%/10.2% | 3.6 ± 1.2/ | 1.2 |
| mental | | | | 5.8 ± 0.7 nm | |
| Example | | | | | |
| 3-2 | | | | | |
| Experi- | ZnO | Ga | 0%/3.3% | 4.3 ± 1.4/ | 1.08 |
| mental | | | | 10.8 ± 1.0 nm | |
| Example | | | | | |
| 4-1 | | | | | |
| Experi- | ZnGaO | | 10.5%/17.3% | 3.5 ± 1.1/ | 1.36 |
| mental | | | | 6.8 ± 0.9 nm | |
| Example | | | | | |
| 4-2 | | | | | |

Referring to Table 4, it can be seen that even when the doping material is Li, Al, or Ga, the particle size is increased after amine treatment, and the relative efficiency after amine treatment is further increased compared to before amine treatment. In Table 4, the relative device efficiency shows efficiency of each experimental example when the efficiency before amine treatment is 1. As shown in Table 4, it can be seen that the overall particle size is increased and the relative device efficiency is improved even when the doping material is varied with other metals. In this case, it can be seen that the doping material content (e.g., amount) is higher and the relative device efficiency is superior when the amine treatment is performed with ZnMO (M being one of Mg, Li, Al, or Ga) than when the amine treatment is performed with ZnO. Hereinafter, a light emitting device including metal oxide nanoparticles according to the present embodiment will be described.

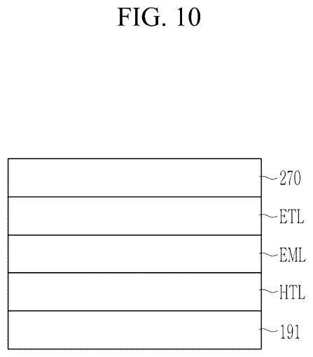

FIG. 10 schematically illustrates a light emitting device according to an embodiment. Referring to FIG. 10, the light emitting device according to the present embodiment may include a first electrode 191, a hole transport layer HTL, an emission layer EML, an electron transport layer ETL and a second electrode 270.

The first electrode 191 and the second electrode 270 may each include a conductive oxide such as an indium tin oxide (ITO), an indium zinc oxide (IZO), a zinc tin oxide (ZTO), a copper indium oxide (CIO), a copper zinc oxide (CZO), a gallium zinc oxide (GZO), an aluminum zinc oxide (AZO), a tin oxide (SnO₂), a zinc oxide (ZnO), or a combination thereof, or a conductive polymer such as calcium (Ca), ytterbium (Yb), aluminum (Al), silver (Ag), magnesium (Mg), samarium (Sm), titanium (Ti), gold (Au) or an alloy thereof, graphene, a carbon nanotube, or PEDOT:PSS. However, the first electrode 191 and the second electrode 270 are not limited thereto, and may be formed in a stacked structure of two or more layers.

In an embodiment, the first electrode 191 may be a reflective electrode having a structure of ITO/Ag/ITO, and the second electrode 270 may be a transflective electrode including AgMg. Light generated from an emission layer EML may be reflected by the first electrode 191, which is a reflecting electrode, and may be resonated between the second electrode 270, which is a transflective electrode, and the first electrode 191 to be amplified. The resonated light may be reflected from the first electrode 191 to be emitted to an upper surface of the second electrode 270.

In some embodiments, the second electrode 270 may be a reflective electrode having a structure of ITO/Ag/ITO, and the first electrode 191 may be a transflective electrode including AgMg. Light generated from an emission layer EML may be reflected by the second electrode 270, which is a reflecting electrode, and may be resonated between the first electrode 191, which is a transflective electrode, and the second electrode 270 to be amplified. The resonated light may be reflected from the second electrode 270 to be emitted to an upper surface of the first electrode 191.

In an embodiment, the second electrode 270 may include an alloy made of two or more materials selected from Ag, Mg, Al, and Yb. More specifically, the second electrode 270 may include AgMg, and in this case, a content (e.g., amount) of Ag in the second electrode 270 may be greater than a content (e.g., amount) of Mg. In this case, the content (e.g., amount) of Mg may be about 10 vol %. A thickness of the second electrode layer 270 may be in a range of 80 Å to 120 Å. In some embodiments, the second electrode 270 may include AgYb, and in this case, a content (e.g., amount) of Yb may be about 10 volume %. However, this is merely an example, and the present disclosure is not limited thereto.

The hole transport layer HTL may include at least one of m-MTDATA, TDATA, 2-TNATA, NPB(NPD), β-NPB, TPD, Spiro-TPD, Spiro-NPB, Methylated-NPB, TAPC, HMTPD, TCTA (4,4′,4″-tris(N-carbazolyl)triphenylamine), Pani/DBSA (Polyaniline/Dodecylbenzenesulfonic acid), PEDOT/PSS (Poly(3,4-ethylenedioxythiophene)/Poly(4-styrenesulfonate))), Pani/CSA (Polyaniline/Camphor sulfonic acid), or PANI/PSS (Polyaniline/Poly(4-styrenesulfonate)). In some embodiments, the hole transport layer may include an alkali metal halide or an alkaline earth metal halide.

The emission layer EML may include an organic material or an inorganic material. The emission layer may include quantum dot(s). For example, the quantum dots may include at least one of Zn, Te, Se, Cd, In, or P. The quantum dots may include a core containing at least one of Zn, Te, Se, Cd, In, or P, and a shell positioned at a portion of the core and having a different composition from that of the core.

For example, the quantum dots may be selected from a group II-VI compound, a group I-III-VI compound, a group III-V compound, a group IV-VI compound, a group IV element, and a group IV compound and a combination thereof.

The quantum dots may be selected from a Group II-VI compound which is selected from a two-element compound selected from CdSe, CdTe, CdS, ZnS, ZnSe, ZnTe, ZnO, HgS, HgSe, HgTe, MgSe, MgS, and a mixture thereof; a three-element compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a four-element compound selected from HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The quantum dot(s) may be selected from a three-element compound selected from AgInS, CuInS, AgGaS, and CuGaS, which are a Group I-III-VI compound, and a mixture thereof or four-element compounds such as AgInGaS and/or CuInGaS.

The Group III-V compound may be selected from a two-element compound selected from GaN, GaP, GaAs, GaSb, AlN, AlP, AlAs, AlSb, InN, InP, InAs, InSb, and a mixture thereof; a three-element compound selected from GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; and a four-element compound selected from GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal (e.g., InZnP), and may be selected from these compounds.

The Group IV-VI compound may be selected from a two-element compound selected from SnS, SnSe, SnTe, PbS, PbSe, PbTe, and a mixture thereof; a three-element compound selected from SnSeS, SnSeTe, SnSTe, PbSeS, PbSeTe, PbSTe, SnPbS, SnPbSe, SnPbTe, and a mixture thereof; and a four-element compound selected from SnPbSSe, SnPbSeTe, SnPbSTe, and a mixture thereof. The Group IV element may be selected from Si, Ge and a mixture thereof, and the Group IV compound may be a two-element compound selected from SiC, SiGe, and a mixture thereof.

The electron transport layer ETL may include the metal oxide nanoparticles described above. A detailed description of the same constituent elements will not be provided. For example, the electron transport layer ETL may include metal oxide nanoparticles, which is a compound represented by Chemical Formula 1.

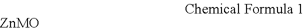

In Chemical Formula 1, M may be one selected from among Ca, Zr, Al, Li, Mg, Ni, Y, W, Co, and Ga.

In some embodiments, the metal oxide nanoparticles according to the present embodiment may include an alkyl amine ligand positioned on a surface thereof. In this case, a number of carbon atoms of the alkyl amine may be 8 to 18.

In some embodiments, a size of the metal oxide nanoparticles according to the present embodiment may be at least 3 nm and at most 20 nm. More specifically, it may be at least 5 nm and at most 20 nm.

For example, the metal oxide nanoparticles included in the electron transport layer ETL of the light emitting device according to the present embodiment may have an alkyl amine ligand having 8 to 18 carbon atoms positioned on a surface thereof by amine treatment as previously described.

This may increase the luminous efficiency of the light emitting device.

Table 5 shows current efficiencies of light emitting devices including the ZnMgO nanoparticles of FIG. 2 and the ZnMgO nanoparticles of FIG. 3 in the electron transport layer.

TABLE 5

| | Example 7 | Example 8 |
|---|---|---|
| | ZnMgO of FIG. 2 | ZnMgO of FIG. 3 |
| | (Before amine | (After amine |
| | treatment) | treatment) |
| Device current | 34.7 cd/A | 50.1 cd/A |
| efficiency | | |

As can be seen in the Table 5, it can be seen that, in the case of Example 8 including metal oxide nanoparticles treated with an amine, the device current efficiency is increased compared to Example 7 including metal oxide nanoparticles not treated with an amine.

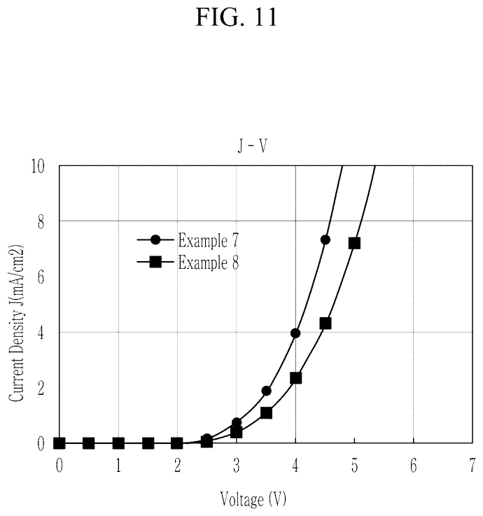

FIG. 11 illustrates a J-V graph for Example 8 including amine-treated metal oxide nanoparticles and Example 7 including non-amine-treated metal oxide nanoparticles. Referring to FIG. 11, it can be seen that the efficiency of Example 8 including metal oxide nanoparticles treated with an amine is improved compared to Example 7 including metal oxide nanoparticles not treated with an amine.

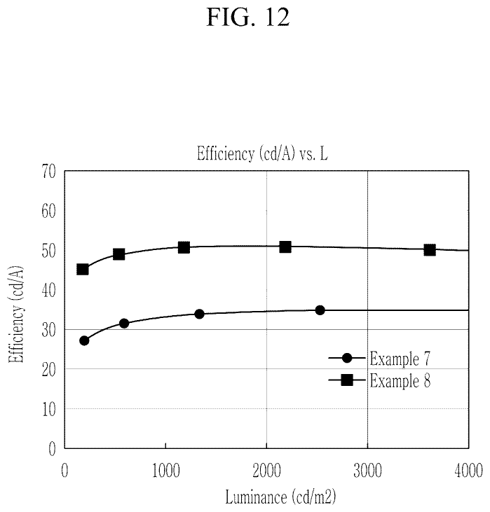

FIG. 12 illustrates light efficiency for Example 8 including amine-treated metal oxide nanoparticles and Example 7 including non-amine-treated metal oxide nanoparticles. Referring to FIG. 12, it can be seen that the efficiency of Example 8 including metal oxide nanoparticles treated with an amine is improved compared to Example 7 including metal oxide nanoparticles not treated with an amine.

As described above, in the metal oxide nanoparticles according to the present embodiment, an alkyl amine ligand having 8 to 18 carbon atoms is positioned on the surface, and these metal oxide nanoparticles may be formed at a temperature of 10° C. or less. The size of the metal oxide nanoparticles thus formed is increased by the amine treatment and the content (e.g., amount) of the dopant M is increased, and when the metal oxide nanoparticles prepared by this preparing method are applied to the electron transport layer of the light emitting device, the light efficiency is improved.

In the present disclosure, singular expressions may include plural expressions unless the context clearly indicates otherwise. It will be further understood that the terms “comprise(s),” “include(s),” or “have/has” when utilized in the present disclosure, specify the presence of stated features, integers, steps, operations, elements, and/or components, but do not preclude the presence or addition of one or more other features, integers, steps, operations, elements, components, and/or groups thereof. The “/” utilized herein may be interpreted as “and” or as “or” depending on the situation.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure”.

In the present disclosure, when particles (e.g., nanoparticles) are spherical, “size” indicates a particle diameter or an average particle diameter, and when the particles are non-spherical, the “size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

As utilized herein, the term “and/or” includes any and all combinations of one or more of the associated listed items. Throughout the disclosure, the expression “at least one of a, b or c”, “at least one of a-c”, “at least one of a to c”, “at least one of a, b, and/or c”, “at least one among a to c”, etc., indicates only a, only b, only c, both (e.g., simultaneously) a and b, both (e.g., simultaneously) a and c, both (e.g., simultaneously) b and c, all of a, b, and c, or variations thereof.

In the present specification, “including A or B”, “A and/or B”, etc., represents A or B, or A and B.

The light-emitting device, the display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

While this present disclosure has been described in connection with what is presently considered to be practical embodiments, it is to be understood that the present disclosure is not limited to the disclosed embodiments, but, on the contrary, is intended to cover one or more suitable modifications and equivalent arrangements included within the spirit and scope of the appended claims and equivalents thereof.

What is claimed is:

1. A metal oxide nanoparticle, comprising:
a compound represented by Chemical Formula 1 and an alkyl amine ligand having 8 to 18 carbon atoms on a surface of the compound: 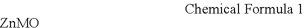
wherein, in Chemical Formula 1, M is one selected from among Ca, Zr, Al, Li, Mg, Ni, Y, W, Co, and Ga.

2. The metal oxide nanoparticle of claim 1, wherein
a size of the metal oxide nanoparticle is at least 3 nm and at most 20 nm.

3. The metal oxide nanoparticle of claim 1, wherein
the metal oxide nanoparticle is composed of one selected from among ZnMgO, ZnLiO, ZnAlO, and ZnGaO.

4. A preparing method of a ZnMgO nanoparticle, the preparing method comprising:
synthesizing ZnMgO utilizing a Sol-Gel at a temperature of at most 10° C.; and
adding an amine to the synthesized ZnMgO.

5. The preparing method of claim 4, wherein
the prepared ZnMgO nanoparticle comprises an alkyl amine ligand having 8 to 18 carbon atoms on a surface of the prepared ZnMgO nanoparticle.

6. The preparing method of claim 4, further comprising
performing surface treatment by adding Mg to the synthesized ZnMgO.

7. The preparing method of claim 4, wherein
a size of the prepared ZnMgO nanoparticle is at least 3 nm and at most 20 nm.

8. The preparing method of claim 4, wherein
a size deviation of the prepared ZnMgO nanoparticle is within 15% based on a median size value of the prepared ZnMgO nanoparticle.

9. The preparing method of claim 4, wherein
a size of the ZnMgO nanoparticle increases through the adding of the amine to the synthesized ZnMgO.

10. A preparing method of a ZnMgO nanoparticle, the preparing method comprising:
synthesizing ZnO utilizing a Sol-Gel at a temperature of at most 10° C.;
obtaining ZnMgO by adding Mg to the synthesized ZnO; and
adding an amine to the obtained ZnMgO.

11. The preparing method of claim 10, wherein
the prepared ZnMgO nanoparticle comprises an alkyl amine ligand having 8 to 18 carbon atoms on a surface of the prepared ZnMgO nanoparticle.

12. The preparing method of claim 10, wherein
a size of the prepared ZnMgO nanoparticle is at least 3 nm and at most 20 nm.

13. The preparing method of claim 10, wherein
a size deviation of the prepared ZnMgO nanoparticle is within 13 based on a median size value of the prepared ZnMgO nanoparticle.

14. The preparing method of claim 10, wherein
a size of the ZnMgO nanoparticle increases through the adding of the amine to the synthesized ZnMgO.

15. A light emitting device, comprising:
a first electrode;
an electron transport layer on the first electrode;
an emission layer on the electron transport layer;
a hole transport layer on the emission layer; and
a second electrode on the hole transport layer,
wherein the electron transport layer comprises a metal oxide nanoparticle,
the metal oxide nanoparticle comprises a compound represented by Chemical Formula 1 and an alkyl amine ligand having 8 to 18 carbon atoms on a surface of the compound: 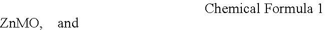
wherein, in Chemical Formula 1, M is one selected from among Ca, Zr, Al, Li, Mg, Ni, Y, W, Co, or Ga.

16. The light emitting device of claim 15, wherein
a size of the light emitting diode nanoparticles is at least 3 nm and at most 20 nm.

17. The light emitting device of claim 15, wherein
the metal oxide nanoparticle is composed of one selected from among ZnMgO, ZnLiO, ZnAlO, and ZnGaO.

18. The light emitting device of claim 15, wherein
a size deviation of the metal oxide nanoparticle in the electron transport layer is within 15% of a median size value of the metal oxide nanoparticle.

19. The light emitting device of claim 15, wherein
the first electrode is a reflecting electrode, and the second electrode is a transflective electrode.

20. The light emitting device of claim 15, wherein
the first electrode is a transflective electrode, and the second electrode is a reflective electrode.
